(19) United States
(12) Patent Application Publication
(10) Pub. No.: US 2017/0236958 A1
(43) Pub. Date: Aug. 17, 2017

(54) PHOTOELECTRIC CONVERSION DEVICE AND PHOTOELECTRIC CONVERSION MODULE

(71) Applicant: KYOCERA Corporation, Kyoto-shi, Kyoto (JP)

(72) Inventors: Hisakazu NINOMIYA, Kirishima-shi (JP); Shintaro KUBO, Kirishima-shi (JP); Toru NAKAYAMA, Kirishima-shi (JP)

(73) Assignee: KYOCERA Corporation, Kyoto-shi, Kyoto (JP)

(21) Appl. No.: 15/502,634

(22) PCT Filed: Sep. 18, 2015
(86) PCT No.: PCT/JP2015/076736

§ 371 Date: Feb. 8, 2017

(30) Foreign Application Priority Data
Sep. 24, 2014 (JP) 2014-193937
Oct. 28, 2014 (JP) 2014-219343
Dec. 25, 2014 (JP) 2014-262680

(51) Int. Cl. H01L 31/0352; H01L 31/05; H01L 31/0725; C01G 9/02; H01L 31/0296

(52) U.S. Cl. CPC H01L 31/035218; C01G 9/02; H01L 31/03529; H01L 31/02963; H01L 31/0725; H01L 31/05; B82Y 30/00

(57) ABSTRACT

The photoelectric conversion device includes a quantum dot accumulation zone, a base layer having current collecting properties which is disposed on at least one major surface of the quantum dot accumulation zone, and a plurality of columnar carrier collection zones, each extending from the base layer into the quantum dot accumulation zone and having an open end. Each of the carrier collection zones is composed mainly of metal oxide. An open end part has a higher mole ratio of oxygen to metal than a body part other than the open end part.

### TECHNICAL FIELD

The present invention relates to a photoelectric conversion device and a photoelectric conversion module.

### BACKGROUND ART

A solar cell including quantum dots which is expected as a next-generation photoelectric conversion device (hereinafter also referred to as “quantum dot solar cell”) is one in which a quantum dot accumulation zone having quantum dots accumulated therein is inserted as a photodetecting layer between two pn-junction semiconductor layers.

The quantum dot solar cell uses, as a carrier, electrons to be excited upon application of sunlight having a predetermined wavelength to the quantum dots, and holes to be generated when the electrons are excited from a valence band to a conduction band.

In this case, photoelectric conversion efficiency of the quantum dot solar cell relates to a total number of carriers generated in the quantum dot accumulation zone. Therefore, an increase in the degree of accumulation of the quantum dots by, for example, increasing the thickness of the quantum dot accumulation zone can contribute to improvement of power generation capacity.

The circumference of the quantum dots is usually surrounded by a barrier layer having a larger band gap than a band gap of the quantum dots themselves. Therefore, it is considered that in theory, energy relaxation due to phonon release of the electrons is less apt to occur and the quantum dots are less apt to disappear.

However, when the quantum dot accumulation zone is formed by accumulating the quantum dots, carriers generated in the quantum dots are apt to disappear after being combined with defects existing in the quantum dot accumulation zone including the barrier layer. This can cause the problem that the density of the carriers is lowered to cause a decrease in electric charge, failing to enhance photoelectric conversion efficiency.

Various structures for enhancing current collecting properties of the carriers in the quantum dot accumulation zone have recently been proposed to solve the above problem. For example, Patent Document 1 describes an embodiment in which a columnar carrier collection zone 107 called nanorod is disposed in a quantum dot accumulation zone 105 that is located between a substrate 101 and an electrode layer 103 and has a plurality of quantum dots 105a loaded therein.

### PRIOR ART DOCUMENT

### Patent Document

Patent Document 1: Japanese Unexamined Patent Publication No. 2009-536790

### SUMMARY OF THE INVENTION

### Problems to be Solved by the Invention

However, even the quantum dot solar cell disclosed in Patent Document 1 has the problem that the collection capability of carriers is still low and short-circuit current density that becomes an index of conversion efficiency of the solar cell is low.

Accordingly, the present invention has its object to provide a photoelectric conversion device and a photoelectric conversion module which have high collection capability of carriers and are hence capable of enhancing short-circuit current density.

### Means for Solving the Problems

A photoelectric conversion device of the present invention includes a quantum dot accumulation zone having a plurality of quantum dots, a base layer having current collecting properties which is disposed on a surface of the quantum dot accumulation zone, and a plurality of columnar carrier collection zones, each extending from the base layer into the quantum dot accumulation zone. Each of the carrier collection zones includes an open end part and a body part other than the open end part, and is composed mainly of metal oxide. The open end part has a higher mole ratio of oxygen to metal than the body part.

The photoelectric conversion module of the present invention includes a plurality of the photoelectric conversion devices, and the photoelectric conversion devices adjacent to each other are electrically connected to each other via a connection conductor.

### Effects of the Invention

With the photoelectric conversion device and the photoelectric conversion module of the present invention, the collection capability of carriers is high and makes it possible to enhance short-circuit current density.

### BRIEF DESCRIPTION OF THE DRAWINGS

FIG. 1 is a schematic sectional view that partially shows a photoelectric conversion device of a first embodiment;

FIG. 2(a) is a schematic sectional view that partially shows a photoelectric conversion device of a second embodiment, and FIG. 2(b) is a sectional view taken along line A-A in FIG. 2(a);

FIG. 3(a) is a schematic sectional view that shows a photoelectric conversion device of a third embodiment in which a part of a plurality of carrier collection zones includes the carrier collection zone having a larger width on an open end side thereof than on a root part side thereof, and FIG. 3(b) is a sectional view taken along line A-A in FIG. 3(a);

FIG. 4 is a schematic sectional view that shows a photoelectric conversion device of a fourth embodiment, specifically an embodiment in which carrier collection zones are in partial contact;

FIG. 5 is a schematic sectional view that shows a photoelectric conversion device of a fifth embodiment, specifically a state in which quantum dots are made up of n-type quantum dots and p-type quantum dots, the n-type quantum dots are disposed close to a carrier collection zone, and the p-type quantum dots are disposed outside the n-type quantum dots;

FIG. 6 is a schematic sectional view that shows a photoelectric conversion device of a sixth embodiment, specifically a multilayered configuration of a photoelectric conversion layer;

FIG. 7(a) to (d) are process drawings that show a method for manufacturing a photoelectric conversion device according to a first embodiment;

FIG. 8(a) to (d) are process drawings that show a method for manufacturing a photoelectric conversion device according to a second embodiment;

FIG. 9(a) is a graph that shows a change of an oxygen/zinc mole ratio constituting carrier collection zones, which is measured with photoelectron spectroscopy, when stirring time of a solution containing zinc is 20 minutes, FIG. 9(b) is a graph that shows a change of the oxygen/zinc mole ratio when the stirring time is 40 minutes, and FIG. 9(c) is a graph that shows a change of the oxygen/zinc mole ratio in the absence of stirring; and

FIG. 10 is a schematic sectional view that shows a conventional quantum dot solar cell.

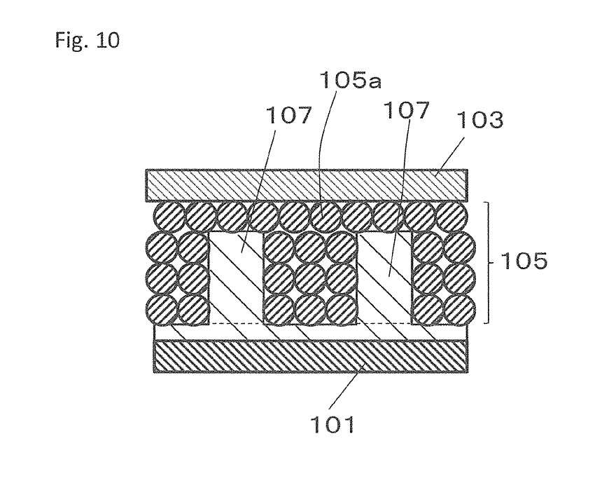

### EMBODIMENTS FOR CARRYING OUT THE INVENTION

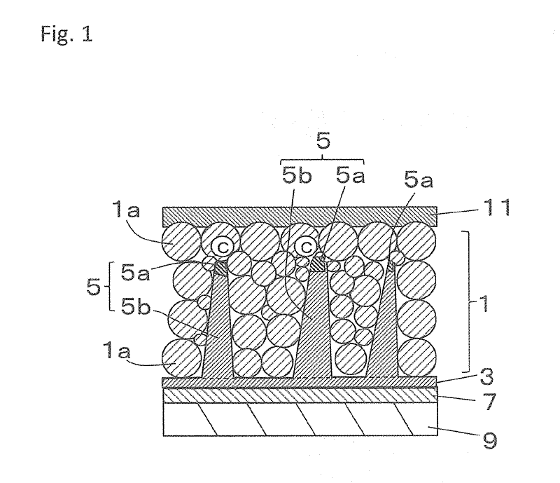

FIG. 1 is a schematic sectional view that partially shows a photoelectric conversion device of a first embodiment. The photoelectric conversion device of the first embodiment includes a quantum dot accumulation zone 1 having a plurality of quantum dots 1a accumulated therein, a base layer 3 having current collecting properties which is disposed on one surface of the quantum dot accumulation zone 1, and a columnar carrier collection zone 5 having current collecting properties and extending in a thickness direction in the quantum dot accumulation zone 1. In FIG. 1, a glass substrate 9 is disposed on a lower surface side of the base layer 3 with a transparent conductive film 7 interposed therebetween. An electrode layer 11 is disposed on an upper surface side of the quantum dot accumulation zone 1. In this case, the glass substrate 9 side becomes a light incident side, and the electrode layer 11 side becomes a light exit side. Here, the carrier collection zone 5 denotes one which has a height of 100 nm or more from a surface of the base layer 3.

The carrier collection zone 5 is disposed so that one open end thereof remains in the quantum dot accumulation zone 1. The carrier collection zone 5 is composed mainly of metal oxide. In this case, an open end part 5a including the open end and a nearby region thereof has a higher mole ratio of oxygen to metal than a body part 5b other than the open end part 5a.

The phrase “composed mainly of the metal oxide” denotes a state in which an element indicating the metal oxide is detectable at an area ratio of 60% or more within a contour of the carrier collection zone 5 when the composition of the carrier collection zone 5 is analyzed. The phrase “the open end part 5a of the carrier collection zone 5” denotes a region not exceeding 50 nm from a tip of the carrier collection zone 5, and another region whose distance from the tip exceeds 50 nm denotes the body part 5b.

When the carrier collection zone 5 is composed mainly of the metal oxide, the short-circuit current density (Jsc) of the photoelectric conversion device can be enhanced by employing, as the carrier collection zone 5, an oxygen-rich one in which the open end part 5a has a large content of oxygen to metal (element).

The reason for this seems to be as follows. When the metal oxide in the open end part 5a as being a tip portion of the carrier collection zone 5 becomes an oxygen-rich composition, a large number of crystals that become a stoichiometry composition exist in the open end part 5a, and therefore, the open end part 5a has a high proportion of metal oxide with a high degree of crystallinity. Consequently, crystal lattice continuity is enhanced to inhibit carrier recombination.

The metal oxide that produces the above characteristics is preferably zinc oxide or titanium oxide. The metal oxide capable of enhancing conductivity according to a change of an oxygen content is suitable for the carrier collection zone 5. In addition to the above characteristics, zinc oxide or titanium oxide also has the advantage of being capable of forming a columnar body with a small surface roughness (Ra) as the carrier collection zone 5, thereby making it possible to bring a large number of quantum dots 1a into contact with the circumference of the carrier collection zone 5. As a measure of the surface roughness (Ra) of the carrier collection zone 5, it is preferably to be 10 nm or less.

In the carrier collection zone 5, a mole ratio of oxygen to metal (element) (oxygen/metal (element)) in the body part 5b is preferably less than 1. For example, when the carrier collection zone 5 is made of a metal oxide composed mainly of zinc oxide, the carrier collection zone 5 described here results in that the body part 5b of the carrier collection zone 5 except for the open end part 5a is in a state of oxygen deficiency, and hence the open end part 5a has a lower carrier density than the body part 5b in the carrier collection region 5. It is therefore conceivable that a potential gradient is apt to occur from the open end part 5a and along the body part 5b, and carrier conductivity from the open end part 5a to the body part 5b is improved, making it possible to enhance collection efficiency of the carriers C.

Here, also in the base layer 3, the mole ratio of oxygen to metal (element) (oxygen/metal (element)) is preferably less than 1. More preferably, the base layer 3 and the carrier collection zone 5 are made of the same material. When the base layer 3 and the carrier collection zone 5 are made of the same material, a crystal structure of the base layer 3 and that of the carrier collection zone 5 have the same crystal system. Accordingly, the continuity of the crystal lattices from the base layer 3 to the carrier collection zone 5 is enhanced to ensure high conductivity from the base layer 3 to the carrier collection zone 5.

In this case, a determination as to whether it is composed mainly of the metal oxide can be made by, for example, an analyzer attached to an electronic microscope. A ratio of the metal (element) and oxygen constituting the carrier collection zone 5 is obtainable with photoelectron spectroscopy. Specifically, the ratio of oxygen to the metal (element) is obtainable from an elemental analysis in a height (thickness) direction of the carrier collection zone 5 by applying electrons to the quantum dot accumulation zone 1 whose surface is exposed. The photoelectron spectroscopy (photoemission spectra) is also suitable means for identifying a major ingredient of the carrier collection zone 5.

The carrier collection zone 5 preferably contains one kind selected from the group consisting of Li, Na, K, Ga, B, and Al as an ingredient other than elements constituting the metal oxide (hereinafter referred to as “secondary ingredient”). When the carrier collection zone 5 contains the secondary ingredient, the density of the carriers C owing to positive ions in the carrier collection zone 5 is improved to enhance the conductivity of the carrier collection zone 5. It is consequently possible to obtain the photoelectric conversion device with high photoelectric conversion efficiency.

In this case, the content of the secondary ingredient contained in the carrier collection zone 5 is preferably 1-5 at %. When the content of the secondary ingredient contained in the carrier collection zone 5 is 1-5 at %, it is possible to ensure a concentration of positive ions contributing to the conductivity of the carrier collection zone 5, and it is also possible to prevent deterioration of weather resistance and deterioration of elastic modulus with a change of the crystal structure of the metal oxide constituting the carrier collection zone 5, which can occur, for example, when the above content exceeds 5 at %. Either one of Na and K is more preferable as the secondary ingredient that brings the above content into an appropriate range.

The secondary ingredient is preferably being dispersed in the open end part 5a and the body part 5b which constitute the carrier collection zone 5. When the secondary ingredient is being dispersed in the open end part 5a and the body part 5b, the conductivity of the carrier collection zone 5 can be further enhanced, thus leading to the carrier collection zone 5 with less variation in collecting capability of the carriers C even when the carriers C that have moved from the quantum dot 1a come into contact with any part of the carrier collection zone 5.

Here, the state in which the secondary ingredient is being dispersed in the open end part 5a and the body part 5b corresponds to the case where, when the secondary ingredient, such as Na and K, is analyzed by, for example, an energy dispersive analyzer attached to a scanning electron microscope, it is possible to observe the state in which the secondary ingredient is dotted all over an analyzed region.

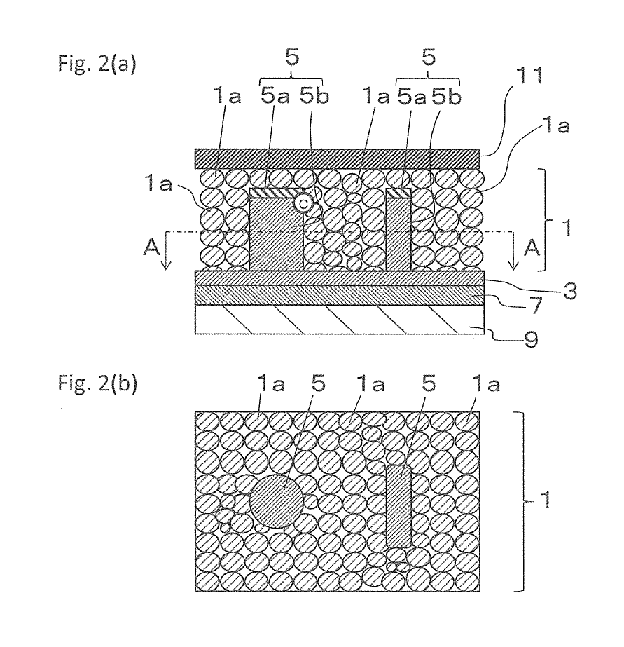

FIG. 2(a) is a schematic sectional view that partially shows a photoelectric conversion device of a second embodiment, and FIG. 2(b) is a sectional view taken along line A-A in FIG. 2(a). In FIGS. 2(a) and 2(b), the width of the carrier collection zone 5 is drawn enlargedly with respect to that shown in FIG. 1 in order that the shape of the carrier collection zone 5 in a transverse plane is clearly understandable. The term “transverse plane” denotes a cross section obtained by cutting the quantum dot accumulation zone 1 along line A-A cross section as shown in FIG. 2(a).

As shown in FIG. 2(a), in the photoelectric conversion device of the second embodiment, the carrier collection zone 5 whose transverse plane has a flat shape is included in part of the carrier collection zones 5 disposed in the quantum dot accumulation zone 1. Hereinafter, the carrier collection zone 5 whose transverse plane has the flat shape is referred to simply as “the flat-shaped carrier collection zone 5.” In the present invention, the fact that the shape in the transverse plane of the carrier collection zone 5 is the flat shape corresponds to one in which an aspect ratio of a planar shape of the transverse plane is only partially 1.5 or more. Here, the aspect ratio is preferably 2 or more.

The photoelectric conversion device of the second embodiment is configured so that the flat-shaped carrier collection zone 5 is included in the part of the carrier collection zones 5 disposed in the photoelectric conversion layer 1 as described above. The flat-shaped carrier collection zone 5 has a larger surface area per unit volume than the case where the transverse plane has an isotropic shape, such as a circle. Hence, even when having the same volume, the carrier collection zone 5 having a larger specific surface area is capable of causing the quantum dots 1a being accumulated in the quantum dot accumulation zone 1, the number of which is larger by that amount, to be contacted with this carrier collection zone 5. Consequently, the collection efficiency of the carriers C in the carrier collection zone 5 is improved to enhance an open circuit voltage (Voc) of the photoelectric conversion device. The reason for this is as follows. When the carrier collection zone 5, whose transverse plane has the flat shape, is included in the carrier collection zones 5, a sum of specific surface areas to be estimated from all the carrier collection zones 5 existing in the quantum dot accumulation zone 1 is larger than a sum of specific surface areas in the case of being made up of the carrier collection zones 5, each having an isotropic-shaped transverse plane.

For example, an area of a side surface of a cylindrical body (with a volume of 31.4) having a radius of 1 and a height of 10 is 62.8. When this is made into a rectangular parallelepiped of the same volume, an aspect ratio thereof is 3.14 when a short side length is set to 1 and a long side length is set to 3.14 in a transverse plane. When a height thereof is set to 10, an area of a side surface of the rectangular parallelepiped is 82.8. The area of the side surface of the rectangular parallelepiped is 1.31 times larger than that of the cylindrical body. Accordingly, in the case of including the flat-shaped carrier collection zone 5 whose transverse plane has an aspect ratio of 1.5 or more, a still larger number of the quantum dots 1a can be brought into contact with the carrier collection zone 5.

Here, a suitable proportion of the flat-shaped carrier collection zones 5, whose aspect ratio of the shape of the transverse plane is 1.5 or more, in the quantum dot accumulation zones 1 is 10% or more in terms of number ratio.

The number ratio of the carrier collection zones 5 included in the quantum dot accumulation zone 1 is obtained from the following method. Firstly, for example, a cross section corresponding to the cross section taken along line A-A shown in FIG. 2(b) is exposed by polishing from the quantum dot accumulation zone 1 constituting the photoelectric conversion device. Subsequently, an electron microscopic observation is carried out with respect to this sample whose cross section is thus exposed. On this occasion, a certain region where 20 to 100 end surfaces of the carrier collection zones 5 are acknowledgeable is determined, observed, and photographed. Thereafter, the size of a shape in a transverse plane is measured on each of the carrier collection zones 5 observed in a photograph thus obtained. When the cross-sectional shape is an approximately circle, firstly, a maximum diameter is obtained, and then measurement is made by using, as a short diameter, a direction perpendicular to a direction that is regarded as the maximum diameter. Subsequently, a value of the maximum diameter/the short diameter is obtained and employed as an aspect ratio. When the cross-sectional shape is a rectangular shape, a long side length and a short side length are obtained. Subsequently, a value of the long side/the short side is obtained and employed as an aspect ratio. Thus, from among all the carrier collection zones 5 existing per unit area, one whose aspect ratio is 1.5 or more is extracted, and a number ratio with respect to a total number is obtained.

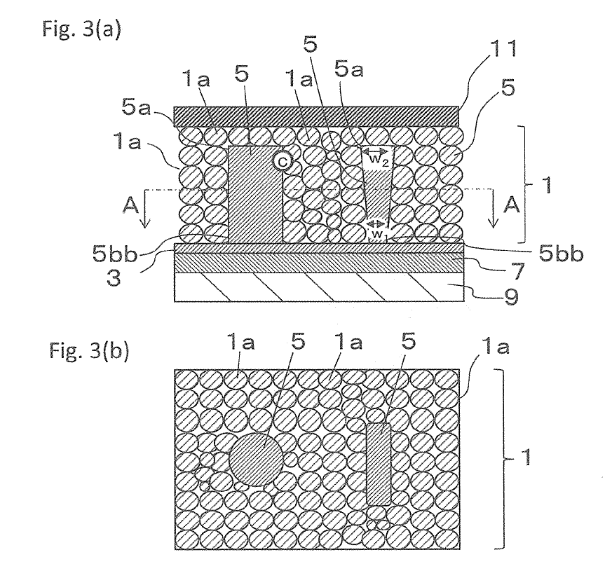

FIG. 3(a) is a schematic sectional view that shows a photoelectric conversion device of a third embodiment in which a part of a plurality of carrier collection zones includes a carrier collection zone having a larger width on an open end side thereof than on a root part side thereof. FIG. 3(b) is a sectional view taken along line A-A in FIG. 3(a).

In a quantum dot accumulation zone 1 shown in FIGS. 3(a) and 3(b), the part of the flat-shaped carrier collection zones 5 includes a carrier collection zone 5 having a larger width on the open end side than on a root part 5bb side. As shown in FIGS. 3(a) and 3(b), the open end side of the carrier collection zone 5 has a larger distance to the base layer 3 than the root part 5bb side, and the carriers C that have entered into the open end side of the carrier collection zone 5 need to move over a longer distance than those that have entered into the root part 5bb side. In this case, resistance loss on the open end side of the carrier collection zone 5 can be reduced by making the width of the open end side (an area of the transverse plane) of the carrier collection zone 5 (here, the carrier collection zone 5 whose transverse plane has the flat shape) larger than that of the root part 5bb side (in FIG. 3(a), the width of the root part 5bb side is represented by w₁, and the width of the open end side is represented by w₂.). This minimizes the difference of resistance between the open end and the root part 5bb of the carrier collection zone 5. It is therefore possible to cause the carriers C that have entered into the open end 5a side to efficiently move to the base layer 3, thereby enhancing the collection efficiency of the carriers C. Here, the width of the open end side denotes the width of the open end part 5a.

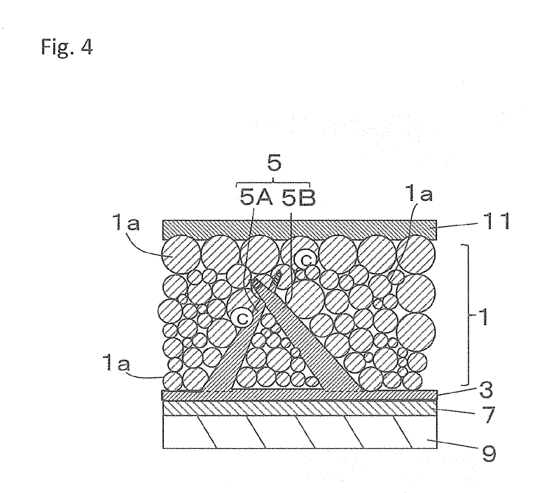

FIG. 4 is a schematic sectional view that shows a photoelectric conversion device of a fourth embodiment, specifically an embodiment in which carrier collection zones are in partial contact.

When the carrier collection zones 5 are disposed in the quantum dot accumulation zone 1, the carrier collection zones 5 being different in extending direction are preferably in partial contact. When the carrier collection zones 5 are disposed in the quantum dot accumulation zone 1, some of these carrier collection zones 5 can have lower conductivity than others. Under the condition that in this situation, the carrier collection zone 5 having low conductivity (tentatively referred to as “carrier collection zone 5A”) and the carrier collection zone 5 having high conductivity (tentatively referred to as “carrier collection zone 5B”) are in contact, even when the carrier collection zone 5A that is already placed in contact with the quantum dot 1a has low conductivity, the carriers C generated in the quantum dot 1a are quickly movable from the carrier collection zone 5A having the low conductivity via the carrier collection zone 5B having the high conductivity to the base layer 3. This makes it possible to enhance the collection efficiency of the carriers C generated in the quantum dot accumulation zone 1, thus leading to improved photoelectric conversion efficiency of the photoelectric conversion device.

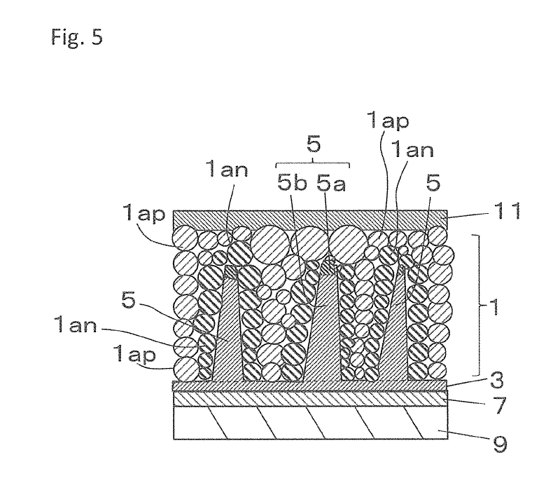

FIG. 5 is a schematic sectional view that shows a photoelectric conversion device of a fifth embodiment, specifically a state in which quantum dots are made up of n-type quantum dots 1an and p-type quantum dots 1ap, the n-type quantum dots 1an are disposed close to the carrier collection zone 5, and the p-type quantum dots 1ap are disposed outside the n-type quantum dots 1an.

When the quantum dots 1a are subjected to light energy, electrons existing in the quantum dots 1a are usually excited to such a level that these electrons have conductivity and, at the same time, holes are formed and these become carriers, so that photoelectric conversion occurs. On this occasion, with such a configuration that the quantum dot accumulation zone 1 is made by laminating a layer composed of the n-type quantum dots 1an on the carrier collection zone 5 and laminating thereon a layer composed of the p-type quantum dots 1ap as shown in FIG. 5, when electrons and holes that are respectively movable to the n-type quantum dots 1an and the p-type quantum dots 1ap are generated, these electrons and holes are respectively more easily movable to the n-type quantum dots 1an and to the p-type quantum dots 1ap, thereby further enhancing the current collecting properties of the carriers.

Although FIG. 5 shows the configuration that the n-type quantum dots 1an are disposed close to the carrier collection zone 5, it is possible to obtain similar photoelectric conversion characteristics even with such a configuration that the p-type quantum dots 1ap are disposed close to the carrier collection zone 5.

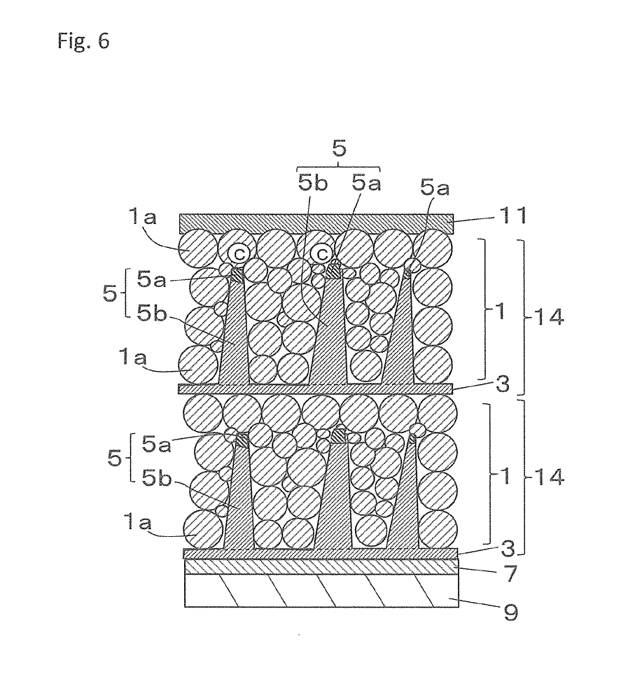

FIG. 6 is a schematic sectional view that shows a photoelectric conversion device of a sixth embodiment, specifically a multilayered configuration for a photoelectric conversion layer.

The photoelectric conversion devices of the first to fifth embodiments have been described above with reference to FIGS. 1 to 5. The photoelectric conversion devices of these embodiments are not limited to the configuration that the photoelectric conversion layer 14 including the carrier collection zones 5, the base layer 3, and the quantum dot accumulation zone 1 is a single layer. Alternatively, the photoelectric conversion layer 14 may be a multilayered one as shown in FIG. 6. In this embodiment, a wavelength region of absorbable light can be widened to achieve still higher photoelectric conversion efficiency by changing the thickness of the quantum dot accumulation zone 1 and the bandgap of the quantum dots 1a in the photoelectric conversion layer 14.

A photoelectric conversion module of the present embodiment includes a panel constituting a photoelectric conversion device group having the photoelectric conversion devices being electrically connected and disposed by a connection conductor, a frame disposed along an outer peripheral part of the panel, and a terminal box with an output cable for supplying electric power generated from the photoelectric conversion devices to an external circuit.

The photoelectric conversion module with large output and high photoelectric conversion efficiency is obtainable by modifying each of the photoelectric conversion devices of the first to sixth embodiments so as to have the configuration of the photoelectric conversion module described above.

Although various semiconductor materials are usable as a material of the quantum dots 1a constituting the foregoing quantum dot accumulation zone 1, one whose energy gap (Eg) is 0.15-2.50 ev is suitable. As a specific semiconductor material, it is preferable to use any one kind selected from among germanium (Ge), silicon (Si), gallium (Ga), indium (In), arsenic (As), antimony (Sb), copper (Cu), iron (Fe), sulfur (S), lead (Pb), tellurium (Te), and selenium (Se), or alternatively their respective compound semiconductors.

Alternatively, the foregoing quantum dots 1a may have a barrier layer on a surface thereof because it is possible to enhance electron confinement effect. A suitable material of the barrier layer has an energy gap that is 2 to 15 times larger than that of the semiconductor material used for the quantum dots 1a. The material of the barrier layer preferably has an energy gap (Eg) of 1.0-10.0 ev. When the quantum dots 1a have the barrier layer on the surface thereof, the material of the barrier layer is preferably a compound (semiconductor, carbide, oxide, or nitride) containing at least one kind element selected from among Si, C, Ti, Cu, Ga, S, In, and Se.

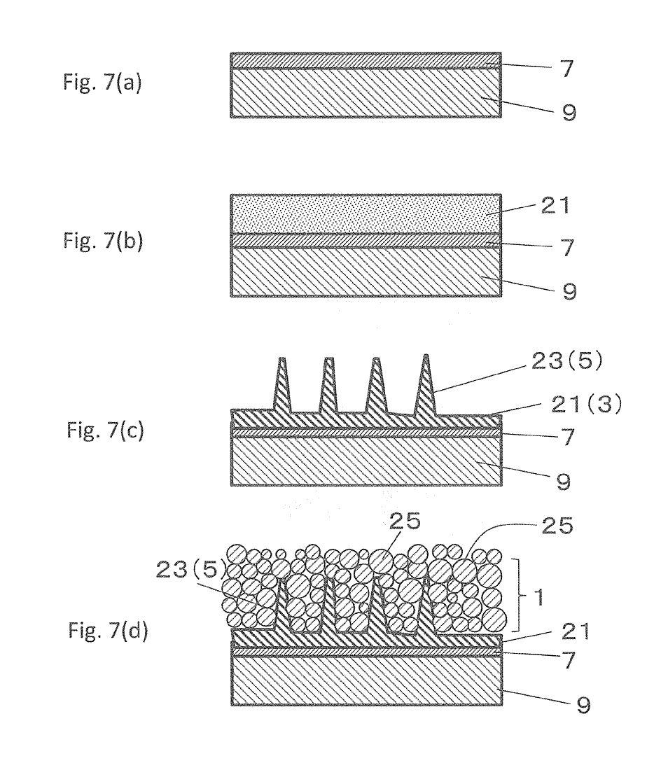

Taking the photoelectric conversion device of the first embodiment as an example, a manufacturing method thereof is described below. FIG. 7(a) to (d) are the process drawings that show the method for manufacturing the photoelectric conversion device of the first embodiment. Firstly, as shown in FIG. 7(a), a glass substrate 9 that becomes a support body is prepared. Subsequently, a transparent conductive film 7 is deposited on a major surface on one side of the glass substrate 9 by using a conductor material, such as indium tin oxide (ITO).

Subsequently, as shown in FIG. 7(b), a nanoparticle layer 21 composed mainly of metal oxide is deposited on a surface of the transparent conductive film 7. For example, when the nanoparticle layer 21 is manufactured using zinc oxide, the nanoparticle layer 21 is deposited by applying a solution containing zinc acetate onto the surface of the transparent conductive film 7 on the glass substrate 9, followed by heating at a temperature of approximately 350° C.

Subsequently, the glass substrate 9 having the transparent conductive film 7 and the nanoparticle layer deposited thereon is immersed in a mixed solution of zinc nitrate and hexamethylenetetramine and is stirred while heating. The heating temperature is preferably 80-120° C. Thus, a columnar crystal 23 of zinc oxide which becomes the carrier collection zone 5 is formable on an upper surface of the nanoparticle layer 21 composed mainly of zinc oxide, as shown in FIG. 7(c). Here, a lower layer side of the nanoparticle layer 21 remains as the base layer 3.

Additionally, by stirring the mixed solution when the glass substrate 9 having the transparent conductive film 7 and the nanoparticle layer 21 deposited thereon is immersed and heated, it is possible to form a portion having a high mole ratio of oxygen to metal (zinc) at a tip of the crystal of zinc oxide that becomes the carrier collection zone 5. Stirring time is set long when enhancing the mole ratio of oxygen to the metal.

When one kind of element selected from the group consisting of Li, Na, K, Ga, B, and Al is contained in the carrier collection zones 5, or in the carrier collection zones 5 and the base layer 3, as a secondary ingredient being ingredient other than the metal oxide, a preparation is made by adding an aqueous solution containing an element (positive ion) that becomes the secondary ingredient into the mixed solution containing zinc nitrate and hexamethylenetetramine.

On this occasion, by using one in which the surface of the glass substrate 9 is processed into a shape having mountain-shaped unevenness, growth directions of two or more columnar crystals 23 are changeable on the mountain-shaped unevenness, thus leading to a structure in which the two or more columnar crystals 23 are contacted with each other. In this case, by further increasing the height of the mountain-shaped unevenness of the glass substrate 9, the columnar crystals 23 grow so as to cross in three dimensions, and therefore the columnar crystals 23 are fused more strongly than the state of being in partial contact therebetween, resulting in a state in which the columnar crystals 23 are partially connected to each other.

Subsequently, as shown in FIG. 7(d), the quantum dot accumulation zone 1 is formed by loading semiconductor particles 25 that become the quantum dots 1a around the columnar crystals 23 that become the carrier collection zones 5 thus obtained, followed by densification processing. As a method of loading the semiconductor particles 25, spin coating method and sedimentation method for a solution containing the semiconductor particles 25 are suitably selected. The densification processing employs a method with which after the semiconductor particles 25 are loaded around the columnar crystals 23, heating or pressurization is carried out, or alternatively both are carried out simultaneously. The thickness of the quantum dot accumulation zone 1 is adjusted according to the mass of the semiconductor particles 25 to be deposited. When multilayering the photoelectric conversion layer 14 including the quantum dot accumulation zone 1, the steps in FIGS. 7(b) to 7(d) need to be repeated.

Finally, a conductor film that becomes the electrode layer 11 is formed by depositing a conductor material, such as gold, on the upper surface side of the quantum dot accumulation zone 1. Subsequently, a protective layer is deposited on a surface of the conductor film, and the protective layer is then covered with a glass film or the like, as needed.

In the flat-shaped carrier collection zone 5 shown in FIG. 2, firstly, a nanoparticle layer 21 is deposited on the surface of the transparent conductive film 7 deposited on the glass substrate 9, and thereafter a mask pattern 22 having openings 22a on an upper surface side of the nanoparticle layer 21 is disposed thereon. In this case, the shape of some of the openings 22a in the mask pattern 22 is made in, for example, a rectangular shape with an aspect ratio of 2, and the rest is made in a circular shape.

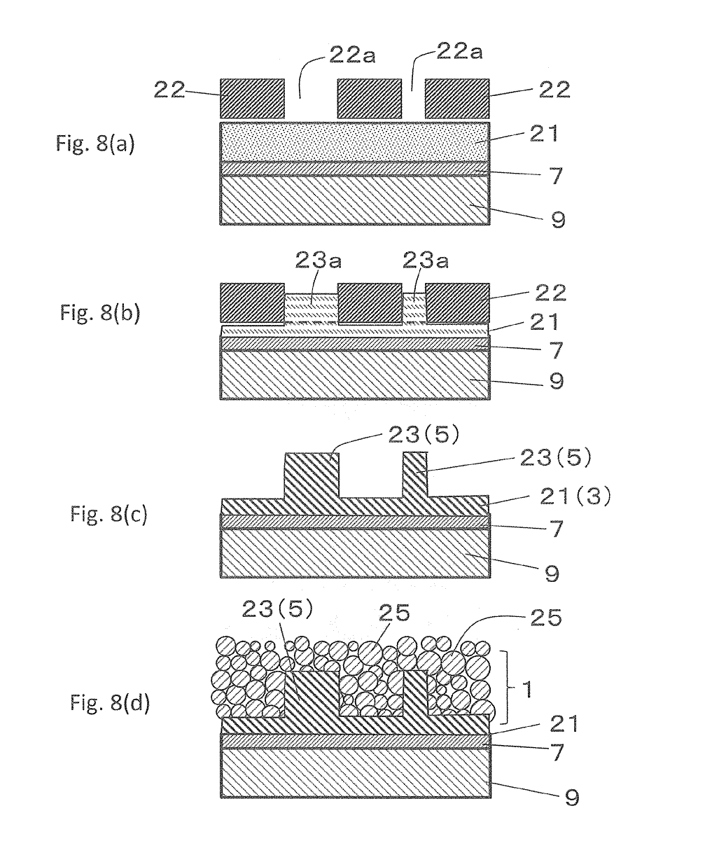

Subsequently, in the state in which the mask pattern 22 is disposed, the glass substrate 9 having the nanoparticle layer 21 and the transparent conductive film 7 deposited thereon is immersed in a mixed solution of zinc nitrate and hexamethylenetetramine and is stirred while heating. Thereby, a film 23a that becomes the columnar crystal 23 grows along the shape of each of the openings 22a of the mask pattern 22 as shown in FIG. 8(b), and the columnar crystal 23 that becomes the carrier collection zone 5 is formable together with the base layer 3 on the transparent conductive film 7 as shown in FIG. 8(c). The following step is similar to that shown in FIG. 7(d).

On this occasion, when the width of the open end side (the area of the transverse plane) of the carrier collection zone 5 whose transverse plane is the flat shape is made larger than that on the root part 5bb side, for example, a mask pattern 22 with openings 22a having a larger diameter than that used in the first half of deposition is used in the second half of the deposition.

The foregoing manufacturing method is not limited to the case where the main ingredient of the base layer 3 and the carrier collection zones 5 is zinc oxide, and is similarly applicable to the case of using other metal oxide (for example, titanium oxide).

### EXAMPLES

The following is an example of manufacturing and evaluating a photoelectric conversion device (quantum dot solar cell) using zinc oxide as a main ingredient of the base layer 3 and the carrier collection zones 5.

Firstly, a glass substrate having an ITO film deposited thereon was prepared. Then, a mixed solution of zinc nitrate (500 mM (milimol)) and hexamethylenetetramine (250 mM (milimol)) was prepared. The carrier collection zones 5 having different mole ratios of oxygen to metal (zinc) were deposited together with the base layer 3 on the ITO film by changing stirring condition to 0 minute, 20 minutes, and 40 minutes.

Subsequently, the quantum dot accumulation zone 1 was formed by applying a solution containing quantum dots of PbS (with a mean particle diameter of 5 nm) prepared in advance, from above the carrier collection zones 5 by spin coating method, followed by densification processing.

Subsequently, a quantum dot solar cell having the carrier collection zones 5 was manufactured by depositing a gold vapor film that becomes the electrode layer 11 on the surface of the quantum dot accumulation zone 1 (stirring time in Sample 1 was 20 minutes, stirring time in Sample 2 was 40 minutes, and stirring time in Sample 3 was zero minute).

A quantum dot solar cell was also manufactured (Sample 4) with a method similar to Sample 1, except that when forming the carrier collection zones 5, 10 mM (milimol)) of an aqueous solution containing sodium (Na) as a secondary ingredient was added in the mixed solution of zinc nitrate (500 mM (milimol)) and hexamethylenetetramine (250 mM (milimol)). Stirring time of the mixed solution containing sodium was set to 20 minutes. The content of sodium contained in the carrier collection zones 5, which was obtained with an analyzer attached to a transmission electron microscope, was approximately 1.5 at %.

Quantum dot solar cells were respectively manufactured (Samples 5, 6, 7, and 8) with a method similar to Sample 1, except that when forming the carrier collection zones 5, the mask pattern 22 having the openings 22a on the upper surface side of the nanoparticle layer 21 was disposed as shown in FIG. 8(a).

Specifically, Sample 5 was manufactured using the mask pattern 22 in which some of the openings 22a have the rectangular shape, and the cross section of some of the carrier collection zones 5 had the flat shape. Sample 6 was manufactured using the mask pattern 22 in which all of the openings 22a had the circular shape in order to compare with Sample 5. In Sample 6, almost all of the cross sections of the carrier collection zones 5 had the circular shape. Sample 7 was manufactured in such a manner that a mask pattern with the openings having a larger diameter than that used in the first half of deposition was used in the second half of the deposition when forming the columnar crystals 5. In Sample 7, the width of the open end side was larger than that on the root part. Sample 8 was manufactured using the mask pattern 22 in order to obtain the state in which the carrier collection zones 5 were in partial contact. Specifically, in the mask pattern 22 used in Sample 8, intervals of the openings 22a were reduced to 80% of that for the mask pattern 22 used for manufacturing the carrier collection zones 5 of Sample 5.

Samples 9, 10, and 11 were respectively manufactured by loading PbS of p-type and n-type into the carrier collection zones 5 manufactured in the same conditions as those in Samples 1, 4, and 5. In these Samples 9, 10, and 11, the n-type quantum dots 1a were close to the carrier collection zones 5, and the p-type quantum dots 1a were disposed outside the n-type quantum dots 1a.

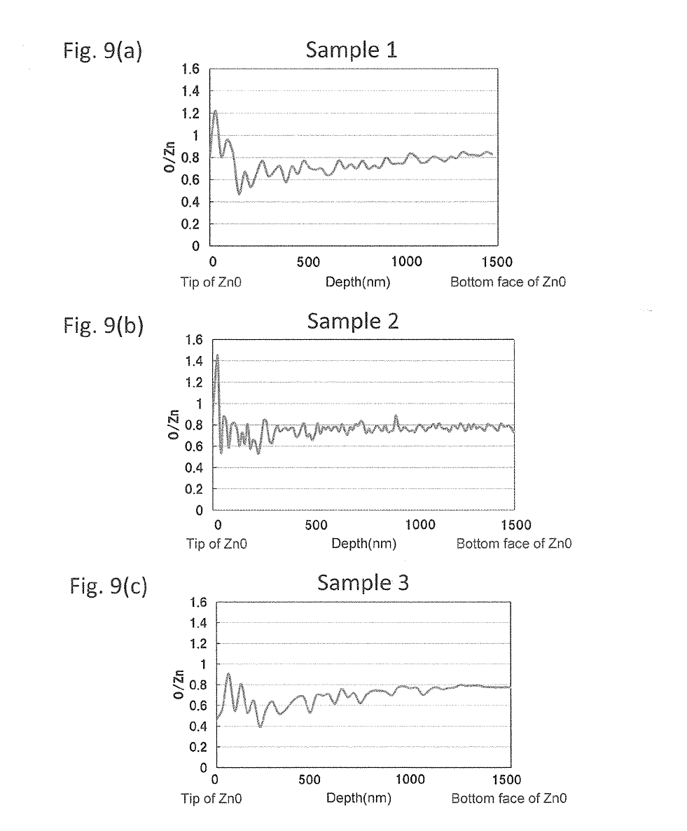

Next, the manufactured quantum dot solar cells were evaluated. Firstly in Samples 1 to 3, the electrode layer 11 side of the quantum dot solar cells was polished to expose the open end side of the carrier collection zones 5, and a ratio of oxygen to zinc was measured from an elemental analysis in the height direction of the carrier collection zones 5 by photoelectron spectroscopy. On this occasion, a determination as to whether the carrier collection zones 5 were composed mainly of metal oxide was also made from photoemission spectra. In the manufactured Samples, the short-circuit current density (Jsc) and the open circuit voltage (Voc) were measured by connecting a lead wire between the transparent conductive film 7 and the electrode layer 11. An example of measurement results of the ratio of oxygen to zinc was shown in FIGS. 9(a), 9(b), and 9(c). FIG. 9(a) corresponds to Sample 1 manufactured by stirring the mixed solution for 20 minutes during immersion and heating. FIG. 9(b) corresponds to Sample 2 manufactured by stirring the mixed solution for 40 minutes during immersion and heating. FIG. 9(c) corresponds to Sample 3 manufactured without stirring. In all of Samples of FIGS. 9(a), 9(b), and 9(c), the mole ratio of oxygen to zinc in the body part 5b of the carrier collection zones 5 was less than 1. Table 1 presents the mole ratio of oxygen to zinc at a position, as the body part 5b, which was located approximately 500 nm from the open end of the carrier collection zone 5 toward the root part.

TABLE 1

| | Carrier collection zone | | | | | | | | | |
|---|---|---|---|---|---|---|---|---|---|---|
| | | | | | Existence | Existence | | | | |
| | | | | | of carrier | of carrier | | | | |
| | Mole | | Existence | | collection | collection | | Quantum | | |
| | ratio | Mole | of the | | zone with | zone having a | Existence | dots | Short- | |
| | at the | ratio | secondary | Use of | flat- | larger width on | of | Existence of | circuit | |
| | open end | of the | ingredient | mask | shaped cross | open end side | partial | p-type and | current | Open |
| | side | body part | (Na) | pattern | section | than on root | connection | n-type | density | circuit |
| Sample | (oxygen/ | (oxygen/ | Yes (○)/ | Yes (○)/ | Yes (○)/ | part end | Yes (○)/ | Yes (○)/ | mA/c | voltage |
| No. | metal) | metal) | No (×) | No (×) | No (×) | Yes (○)/No (×) | No (×) | No (×) | m² | V |
| 1 | 1.2 | 0.8 | × | × | × | × | × | × | 28.5 | 0.37 |
| 2 | 1.4 | 0.8 | × | × | × | × | × | × | 30.6 | 0.37 |
| 3 | 0.9 | 0.7 | × | × | × | × | × | × | 21.6 | 0.31 |
| 4 | 1.2 | 0.8 | ○ | × | × | × | × | × | 31.5 | 0.37 |
| 5 | 1.2 | 0.8 | × | ○ | ○ | × | × | × | 29.4 | 0.37 |
| 6 | 1.2 | 0.8 | × | ○ | × | × | × | × | 27.5 | 0.35 |
| 7 | 1.2 | 0.8 | × | ○ | × | ○ | × | × | 29.9 | 0.39 |
| 8 | 1.2 | 0.8 | × | ○ | × | × | ○ | × | 27.9 | 0.38 |
| 9 | 1.2 | 0.8 | × | × | × | × | ○ | ○ | 29.2 | 0.37 |
| 10 | 1.2 | 0.8 | ○ | × | × | × | ○ | ○ | 32.1 | 0.37 |
| 11 | 1.2 | 0.8 | × | ○ | ○ | × | × | ○ | 30.6 | 0.37 |

As apparent from the results of Table 1, a portion whose mole ratio of oxygen to zinc exceeded 1 was formed at the open end part 5a in Samples other than Sample 3 shown in FIG. 9(c).

The short-circuit current density (Jsc) of the Sample 3 was as low as 21.6 mA/cm², compared to 28.5 mA/cm² in Sample 1 and 30.6 mA/cm² in Sample 2.

In Sample 4 in which sodium (Na) was contained in the carrier collection zones 5 as the secondary ingredient other than the metal oxide, the mole ratio of oxygen to zinc in the open end part 5a was equivalent to that in Sample 1. The short-circuit current density (Jsc) in Sample 4 was 31.5 mA/cm².

In Samples 5 and 6 in which some of the carrier collection zones 5 included the flat-shaped carrier collection zone 5, the mole ratio of oxygen to zinc in the open end part 5a was equivalent to that in Sample 1. The short-circuit current density (Jsc) in Sample 5 was 29.4 mA/cm², that in Sample 6 was 27.5 mA/cm², that in Sample 7 was 29.9 mA/cm², and that in Sample 8 was 27.9 mA/cm².

In Samples 9, 10, and 11 in which PbS of p-type and n-type were loaded in the carrier collection zones 5, the short-circuit current density of each of these samples was higher than that in each of Samples 1, 4, and 5 in which quantum dots containing no dope ingredient was loaded therein. The short-circuit current density in Sample 9 was 29.2 mA/cm², that in Sample 10 was 32.1 mA/cm², and that in Sample 11 was 30.6 mA/cm².

The open circuit voltage of each of Samples was 0.35 V or more, but the open circuit voltage in Sample 3 was 0.31 V.

### DESCRIPTION OF THE REFERENCE NUMERAL

1 quantum dot accumulation zone
1a quantum dot
1ap p-type quantum dot
1an n-type quantum dot
3 base layer
5 carrier collection zone
5a open end part
5b body part
5bb root part
7 transparent conductive film
9 glass substrate
11 electrode layer
13 quantum dot
21 nanoparticle layer
22 mask pattern
22a opening
23 columnar crystal
25 semiconductor particle
C carrier

1. A photoelectric conversion device, comprising:
a quantum dot accumulation zone comprising a plurality of quantum dots;
a base layer having current collecting properties which is disposed on a surface of the quantum dot accumulation zone; and
a plurality of columnar carrier collection zones, each extending from the base layer into the quantum dot accumulation zone and having an open end,
wherein each of the carrier collection zones comprises an open end part and a body part other than the open end part, and is composed mainly of metal oxide, and the open end part has a higher mole ratio of oxygen to metal than the body part.

2. The photoelectric conversion device according to claim 1, wherein the metal oxide is zinc oxide or titanium oxide.

3. The photoelectric conversion device according to claim 1, wherein a mole ratio of oxygen/metal of the metal oxide in the body part is less than 1.

4. The photoelectric conversion device according to claim 1, wherein the carrier collection zones contain, as a secondary ingredient, one kind selected from the group consisting of L1, Na, K, Ga, B, and Al.

5. The photoelectric conversion device according to claim 4, wherein a content of the secondary ingredient is 1-5 at %.

6. The photoelectric conversion device according to claim 4, wherein the secondary ingredient is dispersed in the open end part and the body part.

7. The photoelectric conversion device according to claim 1, wherein part of the carrier collection zones has a flat shape.

8. The photoelectric conversion device according to claim 7, wherein an aspect ratio of a transverse plane of the carrier collection zone having the flat shape is 2 or more.

9. The photoelectric conversion device according to claim 7, wherein the carrier collection zone having the flat shape has a larger width on a side of the open end than on a root part close to the base layer.

10. The photoelectric conversion device according to claim 1, wherein the carrier collection zones comprise carrier collection zones being different in extending direction, and the carrier collection zones being different in the extending direction are in partial contact.

11. The photoelectric conversion device according to claim 1, wherein the quantum dots comprise n-type quantum dots and p-type quantum dots, the n-type quantum dots are disposed around the carrier collection zones, and the p-type quantum dots are disposed outside the n-type quantum dots.

12. The photoelectric conversion device according to claim 1, comprising a plurality of laminated photoelectric conversion layers, each comprising the quantum dot accumulation zone, the base layer, and the carrier collection zones.

13. A photoelectric conversion module, comprising a plurality of the photoelectric conversion devices according to claim 1, the photoelectric conversion devices adjacent to each other being electrically connected to each other via a connection conductor.
